(19) United States
(12) Patent Application Publication
(10) Pub. No.: US 2021/0055340 A1
(43) Pub. Date: Feb. 25, 2021

(54) PROBE CARD

(71) Applicant: Hermes Testing Solutions Inc., Hsinchu City (TW)

(72) Inventors: WEN-YUAN HSU, Hsinchu City (TW); SHIH-YING CHOU, Hsinchu City (TW); SIH-YING CHANG, Hsinchu City (TW)

(21) Appl. No.: 16/545,268

(22) Filed: Aug. 20, 2019

(51) Int. Cl. G01R 31/26; G01R 31/265; G01R 31/28

(52) U.S. Cl. CPC G01R 31/2601; G01R 31/2831; G01R 31/2656

(57) ABSTRACT

A probe card for detecting a wafer. The probe card includes a light-output element, which is connected to a positioning element. The light-output element is set within a through hole of an electrical detection substrate. The light-output element is connected to a light source controller by an optical fiber, thereby an output light can be transmitted from the light source controller to the light-output element. The positioning element can move the light-output element in three-dimensional space or adjust an emitting angle from an axis of the light-output element. Therefore, an optical measurement and an electrical measurement can be implemented at the same time in the silicon photonic wafer test.

### FIELD OF THE INVENTION

The present disclosure relates to a probe card for detecting a wafer, and especially relates to a probe card equipped with an optical measurement device and an electrical measurement device, i.e. a photoelectrical probe card.

### BACKGROUND OF THE INVENTION

In mass production test of silicon photonic wafers, an optical measurement could be used to test the wafer. A mechanical arm, equipped with a light-output element and a Z-axis displacement sensing element, is used to implement the optical measurement, and the light-output element is connected to a light source controller by an optical fiber to transmit an output light. Therefore the light-output element can be moved to the optimal detection position, which can receive the pre-determined luminous flux.

In addition, an electrical measurement could also be used to the wafer via the probe, which can be moved to the testing location of the wafer. The optical measurement is separated from the electrical measurement, i.e. two probes are independent for each other. The optical measurement and the electrical measurement can not be use on the wafer at the same time, and the test is not efficient. In general, it takes 24 hours to test an 8-inch wafer. This invention proposes a photoelectrical probe card to enhance the performance by integrating the optical measurement and the electrical measurement at the same time.

### SUMMARY OF THE INVENTION

In order to enhance the efficiency, the present disclosure provides a probe card, which comprises: an electrical detection substrate with a through hole; a light-output element in the through hole, wherein the light-output element is connected to a light source controller by an optical fiber, which the light source controller provides an output light; and a positioning element configured to drive the light-output element to move in three-dimensional space or to adjust an emitting angle deviating from an axis of the light-output element, which is perpendicular to the electrical detection substrate, i.e. parallel to the normal line of electrical detection substrate.

The positioning element is fixed on the electrical detection substrate and connected to the light-output element, so the positioning element can be moved by the electrical detection substrate, and in addition, the angle of emitting light can be slightly adjusted by the positioning element. The optical measurement and the electrical measurement are simultaneously performed on the same detection position of the wafer to reduce the time to test the wafer, so the detection efficiency can be improved.

### BRIEF DESCRIPTION OF THE DRAWINGS

Various embodiments are depicted in the accompanying drawings for illustrative purposes, and should in no way be interpreted as limiting the scope of the embodiments. Various features of different disclosed embodiments can be combined to form additional embodiments, which are part of this disclosure. The foregoing aspects and many of the attendant advantages of the present disclosure will become more readily appreciated as the same become better understood by reference to the following detailed description, when taken in conjunction with the accompanying drawings, wherein:

FIG. 1 is a schematic view showing a side view of a probe card according to an embodiment of the present invention.

FIG. 2 is a schematic view showing a top view of a probe card according to an embodiment of the present invention.

FIG. 3 is a schematic view showing a side view of a probe card according to another embodiment of the present invention.

FIG. 4 is a schematic view showing a top view of a probe card according to another embodiment of the present invention.

FIG. 5 is a schematic view showing a side view of a probe card according to another embodiment of the present invention.

### DETAILED DESCRIPTION

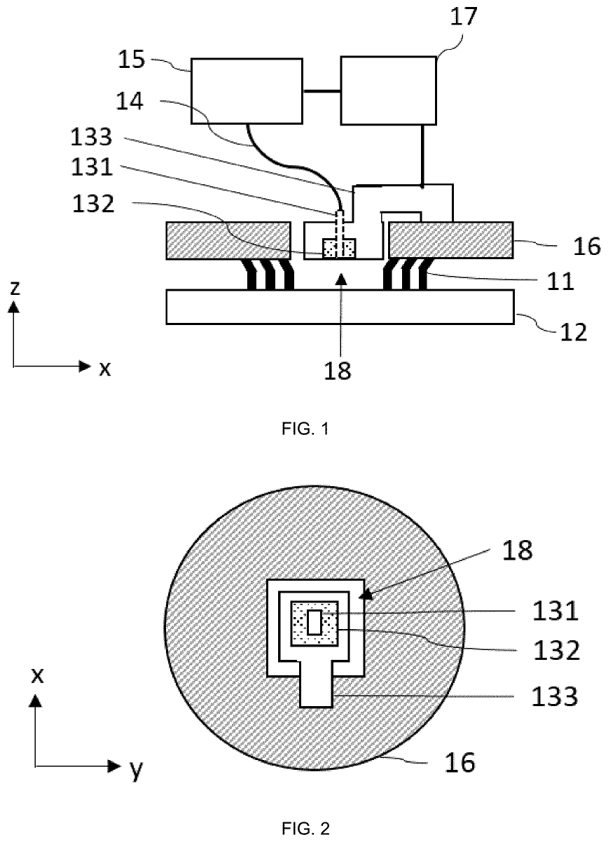

With reference to FIG. 1 and FIG. 2 are schematic views showing a side and a top view of a probe card according to an embodiment of the present invention. The probe card is equipped with devices to implement an optical measurement and an electrical measurement.

An embodiment of the probe card of the present invention comprises an electrical detection substrate 16. The electrical detection substrate 16 has a through hole 18, and a light-output element 131 is set within the through hole 18. It is obvious that the through hole 18 is the movement range of the light-output element 131 in horizontal. The through hole 18 can be anywhere on the electrical detection substrate 16, and located at a center in the embodiment shown as FIG. 2. Besides the external contour of the through hole 18 may be a quadrilateral, a polygon, a circle, or the like, and a rectangle in this embodiment but it should not be limited hereto.

In one embodiment, the positioning element 133, connected to the light-output element 131, is used to control the movement of the light-output component 131 and/or to adjust the angle of light emitted from the light-output component 131, wherein the light-emitting angle is the angle deviated from the normal line of the wafer 12 (i.e. axial line of the light-output element 131). In an embodiment, the positioning element 133 is a multi-axis mechanical arm, such as a six-axis mechanical arm, but is not limited hereto. The positioning element 133 can also be implemented in other manners, it should be understood that any means to drive the light-output element 131 to move within the range of the through hole 18, to adjust the distance between the light-output element 131 and the wafer 12, and/or to adjust the light-emitting angle from the axis of the light-output element 131. In an embodiment, the light-emitting angle ranges from 0 to 10 degrees, and preferably 8 to 10 degrees. The detection range is intersected area, defined by intersecting the light beam and the wafer, which can be adjusted by adjust the light-emitting angle.

In one embodiment, a light source controller 15 comprises a light-emitting element (not shown), which is connected to the light-output element 131 by an optical fiber 14, to provide the output light for the optical measurement. In an embodiment, the light source is a laser.

In one embodiment, the output light is projected onto the wafer 12 via the light output element 131, reflected and then collected by a light sensing element (not shown). The optical property of the surface of the wafer 12 can be analyzed by comparing the reflected light with the emitted light, therefore the probe card has the function of optical measurement. In another embodiment, the output light is projected onto the wafer 12 to change the electrical properties of the wafer 12. The electrical properties can be collected by the electrical detection substrate, and the optical property can be analyzed by compare the electrical properties before and after the light projection, therefore the probe card also has the function of optical measurement. In an embodiment, the integrated controller 17 is configured to perform comparison analysis of the optical property between the output light and the reflected light reflected by the wafer 12, or the electrical properties before and after the light projection.

In an embodiment, the integrated controller 17 is electrically connected to the light source controller 15 and the light sensing element. The emitted light and the reflected light can be compared and analyzed.

In an embodiment, the integrated controller 17 is electrically connected to the light source controller 15 and the electrical detection substrate 16. The electrical properties before and after the light projected on the wafer can be compared and analyzed.

In an embodiment, the integrated controller 17 is further configured to adjust the light emitting unit to control the intensity of the testing light according to the comparison analysis result.

In an embodiment, the light-output element 131 is an array of light-output elements 131 (not shown), and they are independent from each other. Each light-output element 131 is connected to the light source controller 15 by an optical fiber 14, and each can be turn on or off, and the light intensity can be controlled independently. In another embodiment, light-output elements 131 can emit lights with different wavelength.

In an embodiment, the probe card is further equipped with a Z-axis displacement sensing element 132 to sense the distance between the light output element 131 and the wafer 12. The Z-axis displacement sensing element 132 can be connected to the positioning element 133 or the light-output element 131. The point is the Z-axis displacement sensing element 132 and the light-output element 131 should be moved together, so it can sense the distance between the light-output element 131 and the grating or optical channel of the wafer 12. In an embodiment, the Z-axis displacement sensing element 132 is also set within the through hole 18, together with the light-output element 131.

It can be understood that the integrated controller 17 can drive the positioning element 133 to move in the Z-axis direction according to the distance between the light-output element 131 and the wafer 12.

In an embodiment, the integrated controller 17 is electrically connected to the Z-axis displacement sensing element 132 and the positioning element 133. The integrated controller 17 receives the signal of the Z-axis displacement sensing element 132, generates a control signal, and transmits the control signal to the positioning element 133. The positioning element 133 moves in the Z-axis direction according to the control signal.

Therefore, the integrated controller 17 can adjust the light intensity, the emitting angle, the position of the light-output element 131 within the through hole 18, the distance from the wafer 12, and the like.

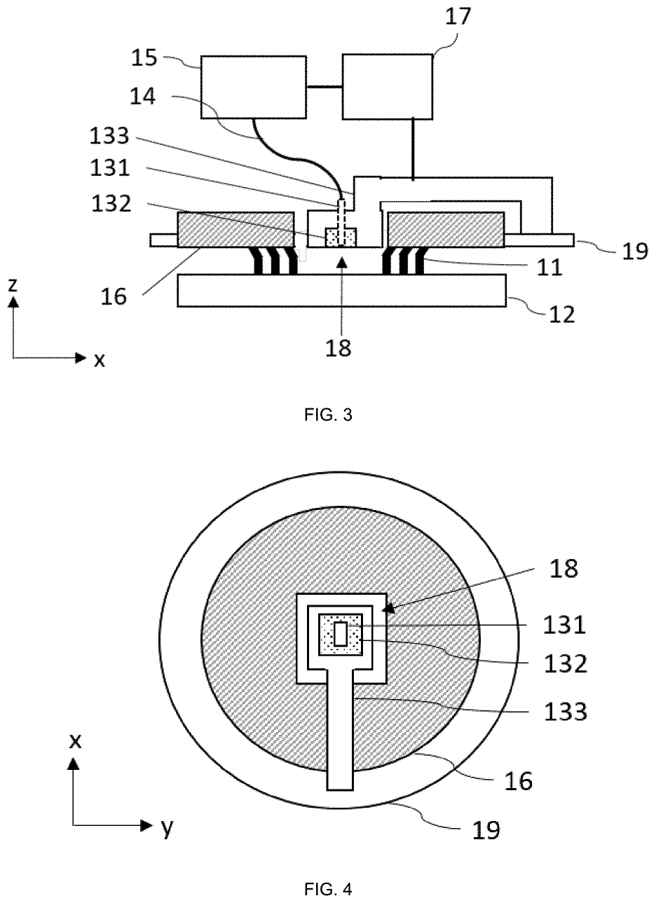

With reference to FIG. 3 and FIG. 4 are schematic views showing a side and a top view of a probe card according to another embodiment, which comprises a platform 19. The platform 19 is used to carry the electrical detection substrate 16, i.e. the electrical detection substrate 16 is fixed on the platform. In an embodiment, the positioning element 133 is fixed on the electrical detection substrate 16. In another embodiment, the positioning element 133 is fixed to the platform 19.

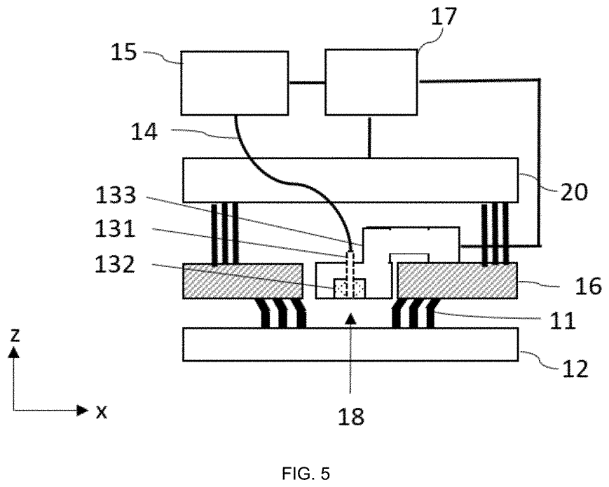

FIG. 5 is a schematic view showing a side view of a probe card according to another embodiment, which further comprises a tester 20. The tester 20, electrically connected to the electrical detection substrate 16 and the integrated controller 17, is used to test specific items on wafers. In an embodiment, the tester 20 can test specific items with specialized parameters. In another embodiment, the tester 20 can be replaced to test the other items on wafer, which depends on detection requirements.

In summary, the probe card proposed here can test optical properties and the electrical properties at the same time. The light source controller provides the output light, the positioning element drives the light-output element to move in the three-dimension and/or to adjust the emitting angle of the output light, and the integrated controller adjusts the intensity of the output light and the detection range according to the detection result. In particular, a tester is used to detect a specific item and can be replaced to test the other items, which depends on the requirement. The efficiency to test a wafer can be solved by integrating the optical measurement and the electrical measurement.

The embodiments described above are merely illustrative of the technical spirit and features of the present disclosure, and are intended to enable those skilled in the art to understand the present disclosure and exploit the present disclosure. The scope of the claim, that is, the equivalent changes or modifications made by the spirit of the present disclosure, should still be included in the scope of the claim of the present disclosure.

What is claimed is:

1. A probe card for detecting a wafer, comprising:
an electrical detection substrate with a through hole, wherein the electrical detection substrate is used to perform an electrical measurement;
a light-output element set within the through hole;
a positioning element configured to drive the light-output element to move in three-dimensional space or to adjust an emitting angle deviated from an axis of the light-output element; and
a light source controller connected to the light-output element by an optical fiber to provide an output light.

2. The probe card of claim 1, wherein the positioning element is connected to the light-output element and the electrical detection substrate.

3. The probe card of claim 1, further comprising a platform to receive the electrical detection substrate.

4. The probe card of claim 3, wherein the positioning element is connected to the light-output element and the electrical detection substrate.

5. The probe card of claim 3, wherein the positioning element is connected to the light-output element and the platform.

6. The probe card of claim 1, further comprising a Z-axis displacement sensing element, wherein the Z-axis displacement sensing element is set within the through hole to sense a distance between the light output element and the wafer.

7. The probe card of claim 1, further comprising an integrated controller for controlling the positioning element and the light source controller.

8. The probe card of claim 1, further comprising a tester, wherein the tester is electrically connected to the electrical detection substrate.

9. The probe card of claim 8, further comprising an integrated controller for controlling the positioning element, the light source controller and the tester.

10. The probe card of claim 1, further comprising a light sensing element for receiving a reflected light, wherein the reflected light is the output light reflected by the wafer.
